(19) United States
(12) Patent Application Publication
(10) Pub. No.: US 2017/0251577 A1
(43) Pub. Date: Aug. 31, 2017

(54) NEAR-FIELD ELECTROMAGNETIC WAVE ABSORBING FILM

(71) Applicant: Seiji KAGAWA, Koshigaya-shi (JP)

(72) Inventor: Seiji KAGAWA, Koshigaya-shi (JP)

(21) Appl. No.: 15/226,366

(22) Filed: Aug. 2, 2016

(30) Foreign Application Priority Data
Feb. 26, 2016 (JP) 2016-036465

(51) Int. Cl. H05K 9/00; H01Q 1/52; H01Q 1/24; H04B 5/00

(52) U.S. Cl. CPC H05K 9/0086; H04B 5/0031; H01Q 1/526; H01Q 1/243

(57) ABSTRACT

A near-field electromagnetic wave absorbing film comprising a thin metal film formed on a surface of a plastic film; the thin metal film being provided with plural lines of laser-etched openings extending and crossing in two directions; pluralities of laser-etched openings being arranged in each line such that at least part of adjacent laser-etched openings are separated; the laser-etched opening lines extending in two directions crossing at an angle of 45-90°; thin metal film portions remaining after forming the laser-etched openings being composed of wide remaining portions partitioned by the laser-etched opening lines, and bridge-like remaining portions connecting adjacent wide remaining portion; and the bridge-like remaining portions having widths of 20 μm or less; thereby having electric resistance of 50-300 Ω/100 cm² and light transmittance (measured with laser rays having a wavelength of 660 nm) of 30-80%.

### FIELD OF THE INVENTION

The present invention relates to a near-field electromagnetic wave absorbing film having high electromagnetic wave absorbability.

### BACKGROUND OF THE INVENTION

Electromagnetic-wave-absorbing sheets for preventing the leakage and intrusion of electromagnetic waves are used for communications apparatuses such as cell phones, smartphones, wireless LANs, etc., and electronic appliances such as computers, etc. Electromagnetic-wave-absorbing sheets widely used at present are constituted by sheets or nets of metals, and electromagnetic-wave-absorbing sheets having metal films vapor-deposited on plastic sheets have recently been proposed. For example, JP 9-148782 A proposes an electromagnetic-wave-absorbing sheet comprising a plastic film, and first and second aluminum films vapor-deposited on both surfaces of the plastic film, the first vapor-deposited aluminum film being etched in a non-conductive linear pattern, and the second vapor-deposited aluminum film being etched in a conductive network pattern.

WO 2010/093027 discloses a composite film comprising a plastic film, and a single- or multi-layered thin metal film formed on at least one surface of the plastic film, the thin metal film being provided with large numbers of substantially parallel, intermittent linear scratches with irregular widths and intervals in plural directions, thereby having reduced anisotropy of electromagnetic wave absorbability.

In the electromagnetic-wave-absorbing sheet of JP 9-148782 A and the composite film of WO 2010/093027 having a linearly scratched thin metal film and a plastic film, electromagnetic wave absorbability is obtained by linear patterns or scratches. Apart therefrom, it is also desired to efficiently form an electromagnetic wave absorbing film having excellent electromagnetic wave absorbability by laser beam spot patterns.

### OBJECT OF THE INVENTION

Accordingly, an object of the present invention is to provide a near-field electromagnetic wave absorbing film having laser-etched openings formed in a thin metal film for good electromagnetic wave absorbability with reduced anisotropy.

### SUMMARY OF THE INVENTION

As a result of intensive research in view of the above object, the inventor has found that (a) the formation of plural lines of laser-etched openings in two directions on a thin metal film formed on a plastic film, such that at least part of adjacent laser-etched openings are separated, provides a near-field electromagnetic wave absorbing film having excellent electromagnetic wave absorbability with small anisotropy. The present invention has been completed based on such finding.

Thus, the near-field electromagnetic wave absorbing film of the present invention comprises a plastic film, and a single- or multi-layered thin metal film formed on a surface of the plastic film;

the thin metal film being provided with plural lines of laser-etched openings extending and crossing in two directions;

pluralities of the laser-etched openings being arranged in each line such that at least part of adjacent laser-etched openings are separated;

the laser-etched opening lines extending in two directions crossing at an angle of 45-90°;

thin metal film portions remaining after forming the laser-etched openings being composed of wide remaining portions partitioned by the laser-etched opening lines, and bridge-like remaining portions connecting adjacent wide remaining portions; and

the bridge-like remaining portions having widths of 20 μm or less;

whereby the near-field electromagnetic wave absorbing film has electric resistance of 50-300 Ω/100 cm² and light transmittance (measured with laser rays having a wavelength of 660 nm) of 30-80%.

The bridge-like remaining portions preferably have an average width of 2-15 μm.

The crossing angle of the laser-etched opening lines is preferably 60-90°.

The laser-etched openings preferably have diameters of 100 μm or less.

The centerline distance between adjacent laser-etched opening lines is preferably 1.5-5 times the diameters of the laser-etched openings.

The thickness of the thin metal film is preferably 10-300 nm.

The thin metal film is preferably made of at least one metal selected from the group consisting of aluminum, copper, silver, tin, nickel, cobalt, chromium, and alloys thereof.

### BRIEF DESCRIPTION OF THE DRAWINGS

FIG. 1 is a partial enlarged plan view showing a near-field electromagnetic wave absorbing film according to one embodiment of the present invention.

FIG. 2(a) is a cross-sectional view taken along the line A-A in FIG. 1.

FIG. 2(b) is a cross-sectional view taken along the line B-B in FIG. 1.

FIG. 3 is a partial enlarged view of FIG. 1.

FIG. 4 is a partial enlarged plan view showing a near-field electromagnetic wave absorbing film according to another embodiment of the present invention.

FIG. 5 is a partial enlarged view of FIG. 4.

FIG. 6(a) is a perspective view showing an apparatus for measuring the electric resistance of a near-field electromagnetic wave absorbing film.

FIG. 6(b) is a plan view showing the measurement of the electric resistance of a near-field electromagnetic wave absorbing film using the apparatus of FIG. 6(a).

FIG. 6(c) is a cross-sectional view taken along the line C-C in FIG. 6(b).

FIG. 7(a) is a plan view showing a system for evaluating the electromagnetic wave absorbability of a near-field electromagnetic wave absorbing film.

FIG. 7(b) is a partially cross-sectional front view showing a system for evaluating the electromagnetic wave absorbability of a near-field electromagnetic wave absorbing film.

FIG. 8 is a photomicrograph showing the near-field electromagnetic wave absorbing film of Example 1.

FIG. 9 is a photomicrograph showing the near-field electromagnetic wave absorbing film of Comparative Example 1.

FIG. 10 is a photomicrograph showing the near-field electromagnetic wave absorbing film of Comparative Example 2.

FIG. 11 is a graph showing the relations between S₁₁ and the frequency of incident electromagnetic waves in the near-field electromagnetic wave absorbing films of Example 1 and Comparative Examples 1 and 2.

FIG. 12 is a graph showing the relations between a transmission attenuation power ratio Rtp and the frequency of incident electromagnetic waves in the near-field electromagnetic wave absorbing films of Example 1 and Comparative Examples 1 and 2.

FIG. 13 is a photomicrograph showing the near-field electromagnetic wave absorbing film of Example 2.

FIG. 14 is a photomicrograph showing the near-field electromagnetic wave absorbing film of Comparative Example 3.

FIG. 15 is a photomicrograph showing the near-field electromagnetic wave absorbing film of Comparative Example 4.

FIG. 16 is a graph showing the relations between S₁₁ and the frequency of incident electromagnetic waves in the near-field electromagnetic wave absorbing films of Example 2 and Comparative Examples 3 and 4.

FIG. 17 is a graph showing the relations between a transmission attenuation power ratio Rtp and the frequency of incident electromagnetic waves in the near-field electromagnetic wave absorbing films of Example 2 and Comparative Examples 3 and 4.

FIG. 18 is a graph showing the relation between a noise absorption ratio Pₗₒₛₛ/Pᵢₙ and the frequency of incident electromagnetic waves in the near-field electromagnetic wave absorbing film of Example 2.

### DESCRIPTION OF THE PREFERRED EMBODIMENTS

The embodiments of the present invention will be explained in detail referring to the attached drawings, and it should be noted that explanation concerning one embodiment is applicable to other embodiments unless otherwise mentioned. Also, the following explanation is not restrictive, and various modifications may be made within the scope of the present invention.

[1] Near-Field Electromagnetic Wave Absorbing Film

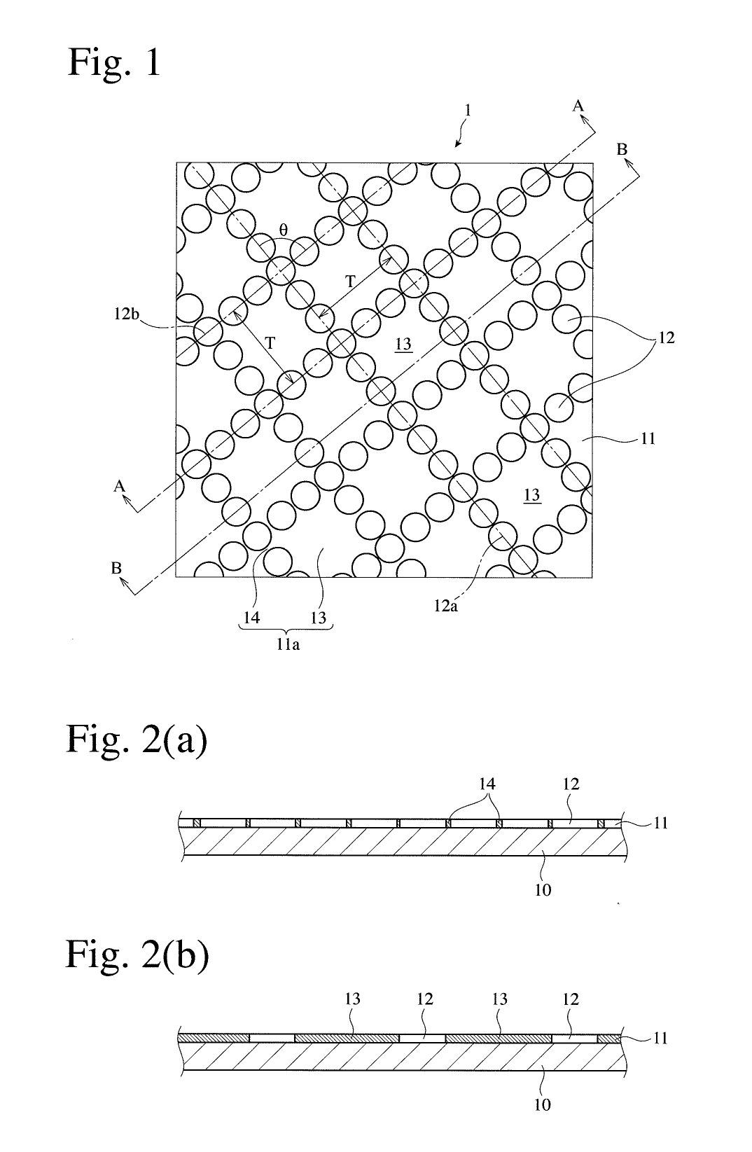

FIGS. 1 and 2 show a near-field electromagnetic wave absorbing film 1 according to a preferred embodiment of the present invention. This near-field electromagnetic wave absorbing film 1 comprises a single- or multi-layered thin metal film 11 formed on a surface of a plastic film 10, the thin metal film 11 being provided with plural lines of laser-etched openings 12 extending and crossing in two directions.

(1) Plastic Film

Resins forming the plastic film 10 are not particularly restrictive as long as they have sufficient strength, flexibility and workability in addition to insulation, and they may be, for instance, polyesters (polyethylene terephthalate, etc.), polyarylene sulfide (polyphenylene sulfide, etc.), polyamides, polyimides, polyamideimides, polyether sulfone, polyetheretherketone, polycarbonates, acrylic resins, polystyrenes, polyolefins (polyethylene, polypropylene, etc.), etc. From the aspect of strength and cost, polyethylene terephthalate (PET) is preferable. The thickness of the plastic film 10 may be about 10-100 μm.

(2) Thin Metal Film

Though not limited as long as they are conductive, metals forming the thin metal film 11 are preferably aluminum, copper, silver, tin, nickel, cobalt, chromium, and alloys thereof, particularly aluminum, copper, nickel and these alloys, from the aspect of corrosion resistance and cost. The thickness of the thin metal film is preferably 10-300 nm, more preferably 20-200 nm, most preferably 30-150 nm. The thin metal film 11 can be formed by vapor deposition (physical vapor deposition such as vacuum vapor deposition, sputtering, ion plating, etc.; or chemical vapor deposition such as plasma-CVD, thermal-CVD, photo-CVD, etc.), plating, or foil-bonding.

When the thin metal film 11 has a single layer, the thin metal film 11 is preferably made of aluminum or nickel from the aspect of conductivity, corrosion resistance and cost. When the thin metal film 11 has pluralities of layers, one may be made of a non-magnetic metal, and the other may be made of a magnetic metal. The non-magnetic metal may be aluminum, copper, silver, tin or an alloy thereof, and the magnetic metal may be nickel, cobalt, chromium or an alloy thereof. As long as their total thickness is within the above range, the non-magnetic metal layer and the magnetic metal layer are not restricted in thickness.

(3) Laser-Etched Opening Lines

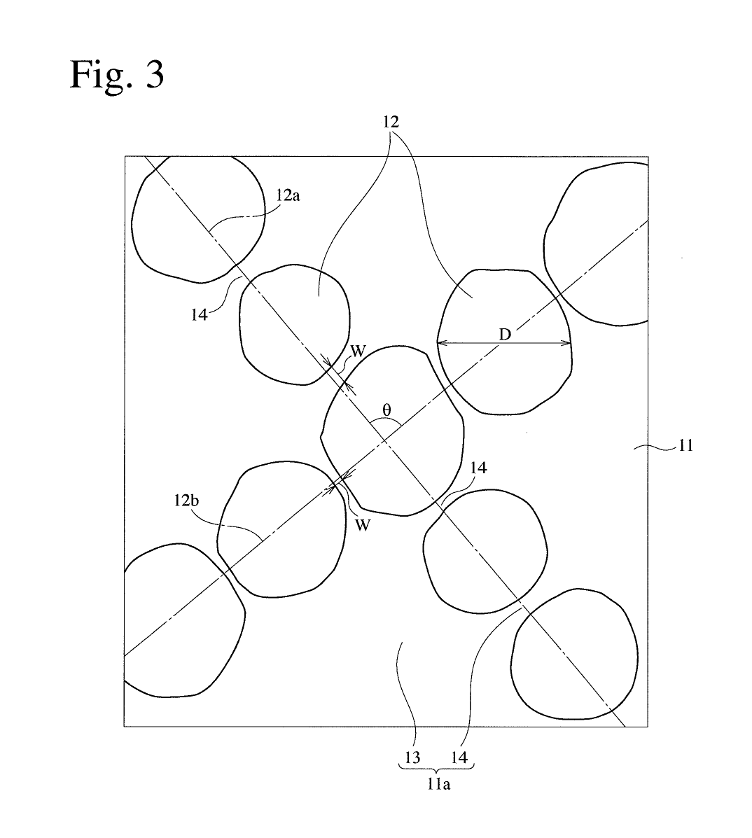

As shown in FIGS. 1-3, each laser-etched opening 12 is a substantially circular opening formed by evaporating a metal by irradiating the thin metal film 11 with laser beam spots, without boring the plastic film 10. The diameter D of each laser-etched opening 12 is preferably 100 μm or less, more preferably 40-80 μm.

Plural lines of laser-etched openings 12 are arranged in the thin metal film 11, such that they extend and cross in two directions. The thin metal film 11 is partitioned by crossing laser-etched opening lines 12a, 12b to individual wide remaining portions 13. In each laser-etched opening line 12a, 12b, pluralities of laser-etched openings 12 are arranged such that at least part of adjacent laser-etched openings are separated, so that there remains a narrow bridge-like remaining portion 14 between separated adjacent laser-etched openings 12 of the thin metal film 11. Accordingly, portions of the thin metal film remaining after forming the laser-etched openings 12, which are called remaining thin metal film portions, are composed of wide remaining portions 13 and narrow bridge-like remaining portions 14.

In both laser-etched opening lines 12a, 12b, at least part of adjacent laser-etched openings 12 are preferably separated. The widths W of the bridge-like remaining portions 14 are 20 μm or less, preferably 1-15 μm. Accordingly, the maximum width Wmax of the bridge-like remaining portions 14 is 20 μm, preferably 15 μm. The average width Way of the bridge-like remaining portions 14 is 2-15 μm, preferably 3-10 μm.

In order that the bridge-like remaining portions 14 have different widths W, the thin metal film 11 may be irradiated with laser beam spots at different intervals.

Though a laser beam spot per se is circular, a region of the thin metal film evaporated by a laser beam spot is not completely circular, but tends to have slightly irregular contour due to interference between adjacent laser-etched openings 12. For example, when adjacent laser-etched openings 12 are not separated, both laser-etched openings 12, 12 are likely merged, or bridge-like remaining portions 14 likely have too small widths. This appears to be due to the fact that the evaporated metal is solidified between adjacent laser beam spots, resulting in too narrow bridge-like remaining portions 14. Because laser-etched openings 12 actually formed by evaporating the thin metal film 11 do not have the same interval even though laser beam spots are arranged with the same interval, bridge-like remaining portions 14 tend to have different widths W within a range of 20 μm or less. Accordingly, the near-field electromagnetic wave absorbing film of the present invention 1 has excellent electromagnetic wave absorbability in a wide frequency range.

The laser-etched opening lines 12a, 12b extending in two directions cross with an angle θ of 45-90°. This provides high electromagnetic wave absorbability with reduced anisotropy. When the crossing angle θ is less than 45°, sufficient electromagnetic wave absorbability cannot be exhibited. When the crossing angle θ is 90°, the maximum electromagnetic wave absorbability is obtained. The preferred crossing angle θ is 60-90°.

The centerline distance T between adjacent laser-etched opening lines 12a, 12b largely affects the sizes of wide remaining portions 13, which in turn affect the electric resistance (thus, electromagnetic wave absorbability) of the near-field electromagnetic wave absorbing film 1. Accordingly, the centerline distance T between the laser-etched opening lines 12a, 12b should be set to obtain desired electric resistance. Specifically, the centerline distance T between the laser-etched opening lines 12a, 12b is preferably 100-400 μm, more preferably 150-300 μm.

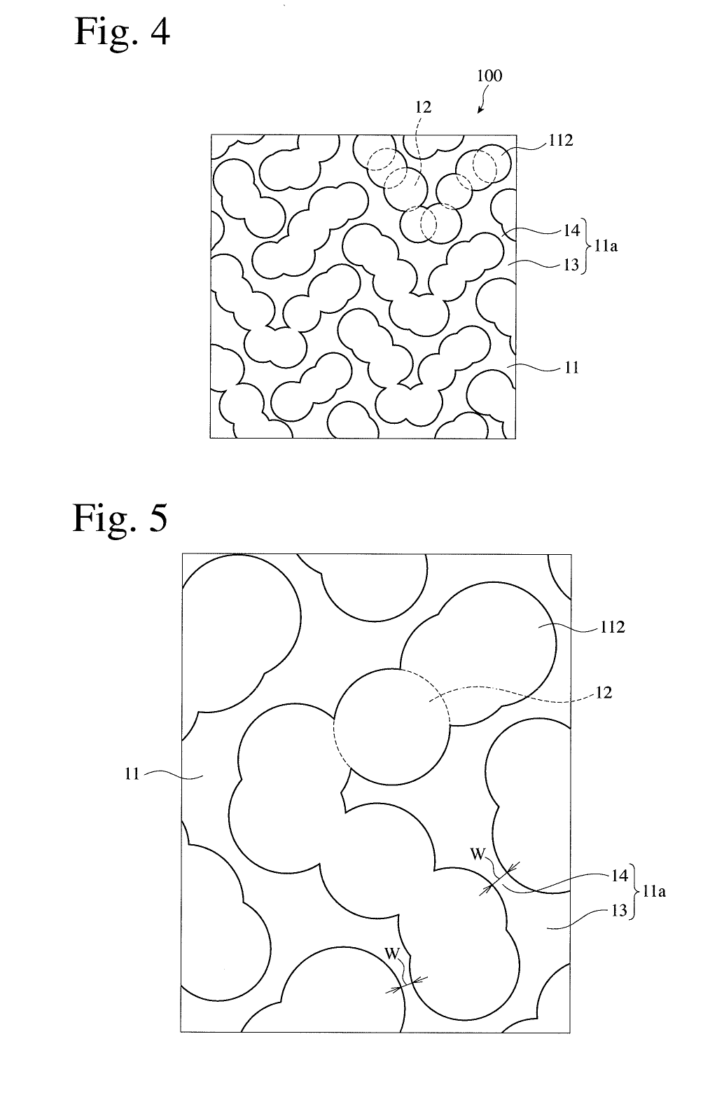

FIGS. 4 and 5 show a near-field electromagnetic wave absorbing film 100 according to another preferred embodiment of the present invention. This near-field electromagnetic wave absorbing film 100 has pluralities of laser-etched openings 12, which are integrally merged into elongated openings 112 [portions from which the thin metal film disappears (evaporated)]. As a result, thin metal film portions remaining after forming the laser-etched openings 12 are composed of wide remaining portions 13 partitioned by the integral openings 112, and bridge-like remaining portions 14 connecting adjacent wide remaining portions 13. In this embodiment, because of relatively small wide remaining portions 13, remaining thin metal film portions 11a composed of the wide remaining portions 13 and the bridge-like remaining portions 14 look like a network as a whole.

In this embodiment, the thin metal film 11 may be irradiated with laser beam spots at different intervals, such that part of adjacent laser-etched openings 12 are integrally connected.

The sizes of wide remaining portions 13 may vary depending on the widths W and number of bridge-like remaining portions 14, the type and thickness of the thin metal film 11 (electric resistance), etc. In general, larger wide remaining portions 13 are obtained when the thin metal film 11 is formed by a metal having larger electric resistance, and when the thin metal film 11 is thinner. Intensive research has revealed that the electromagnetic wave absorbability of the near-field electromagnetic wave absorbing film 1 depends on the size and electric resistance of thin metal film portions remaining after forming laser-etched openings 12 (remaining thin metal film portions 11a=wide remaining portions 13+bridge-like remaining portions 14). Specifically, with electric resistance of 50-300 Ω/100 cm² and light transmittance (measured with laser rays having a wavelength of 660 nm) of 30-80%, the near-field electromagnetic wave absorbing film 1 has excellent absorbability to wide-frequency electromagnetic waves, with low anisotropy.

(4) Electric Resistance

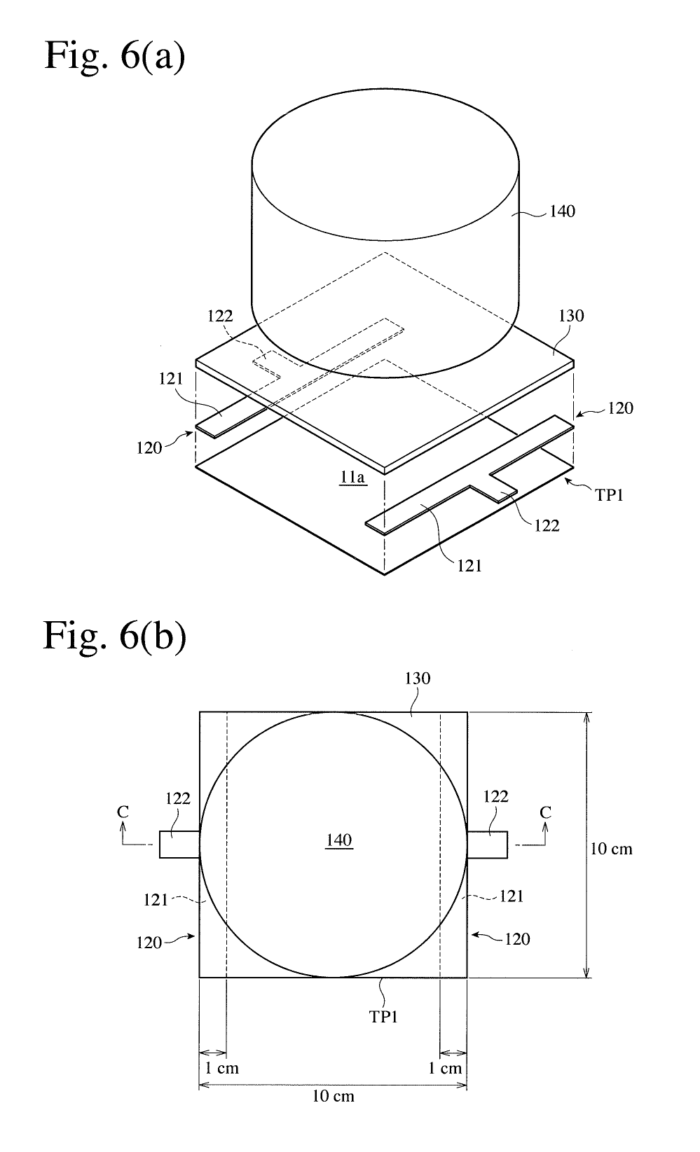

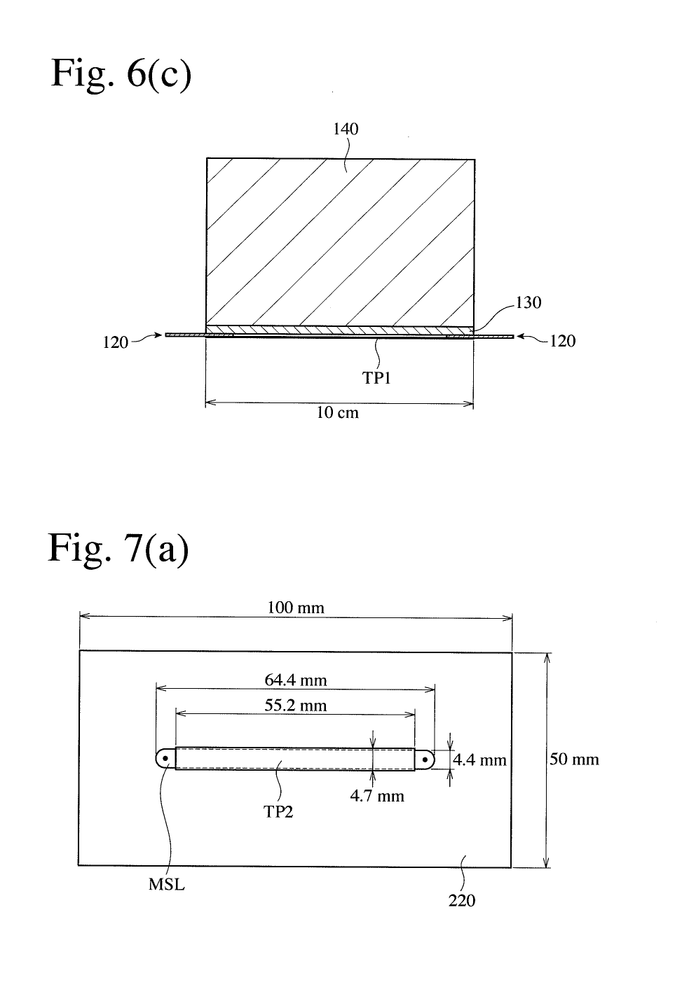

The electric resistance of the near-field electromagnetic wave absorbing film 1 having remaining thin metal film portions 11a is measured by a DC two-terminal method under pressure (simply called “under-pressure two-terminal method”), using an apparatus shown in FIGS. 6(a)-6(c). Specifically, a square test piece TP1 (10 cm×10 cm) of the near-field electromagnetic wave absorbing film 1 is placed with its remaining thin metal film portions 11a above on a flat, hard insulation surface, a pair of electrodes 120, 120 each comprising an electrode body portion 121 of 10 cm in length, 1 cm in width and 0.5 mm in thickness, and an electrode extension 122 of 1 cm in width and 0.5 mm in thickness extending from a center side of the electrode body portion 121 are attached to opposing side portions of the square test piece TP1. A transparent acrylic plate 130 of 10 cm×10 cm×5 mm is placed on the test piece TP1 and both electrodes 120, 120, such that it completely covers them, and a cylindrical weight 140 (3.85 kg) of 10 cm in diameter is placed on the transparent acrylic plate 130, to measure current flowing between both electrode extensions 222, 222 to determine the surface resistance of the near-field electromagnetic wave absorbing film 1.

The near-field electromagnetic wave absorbing film 1 should have electric resistance in a range of 50-300 Ω/100 cm². When the electric resistance is less than 50 Ω/100 cm² or more than 300 Ω/100 cm², the near-field electromagnetic wave absorbing film 1 does not have sufficient electromagnetic wave absorbability. The electric resistance of the near-field electromagnetic wave absorbing film 1 is preferably 60-250 Ω/100 cm², more preferably 80-200 Ω/100 cm².

(5) Light Transmittance

The electromagnetic wave absorbability of the near-field electromagnetic wave absorbing film 1 depends on the area ratio of the remaining thin metal film portions 11a (wide remaining portions 13+bridge-like remaining portions 14). Because the remaining thin metal film portions 11a have substantially no light transmittance, the area ratio of the remaining thin metal film portions 11a can be expressed by the light transmittance of the near-field electromagnetic wave absorbing film 1. The light transmittance of the near-field electromagnetic wave absorbing film 1 is measured with laser rays having a wavelength of 660 nm.

When the light transmittance of the near-field electromagnetic wave absorbing film 1 should be in a range of 30-80%. When the light transmittance is less than 30%, the area ratio of the remaining thin metal film portions 11a is too large, resulting in high reflectance of electromagnetic waves, and thus low electromagnetic noise absorbability. On the other hand, when the light transmittance is more than 80%, the area ratio of the remaining thin metal film portions 11a is too small, resulting in insufficient electromagnetic wave absorbability. The light transmittance of the near-field electromagnetic wave absorbing film 1 is preferably 35-70%.

(6) Protective Layer

A protective plastic layer (not shown) is preferably formed on a thin metal film having plural lines of laser-etched openings 12 extending and crossing in two directions. A plastic film for the protective plastic layer may be the same as the plastic film 10. The thickness of the protective plastic layer is preferably about 10-100 μm. To prevent detachment, a plastic film is preferably heat-laminated to the near-field electromagnetic wave absorbing film 1 as a protective layer. When the protective plastic layer is formed by a PET film, the heat lamination temperature may be 110-150° C.

[2] Electromagnetic Wave Absorbability of Near-Field Electromagnetic Wave Absorbing Film

(1) Transmission Attenuation Power Ratio

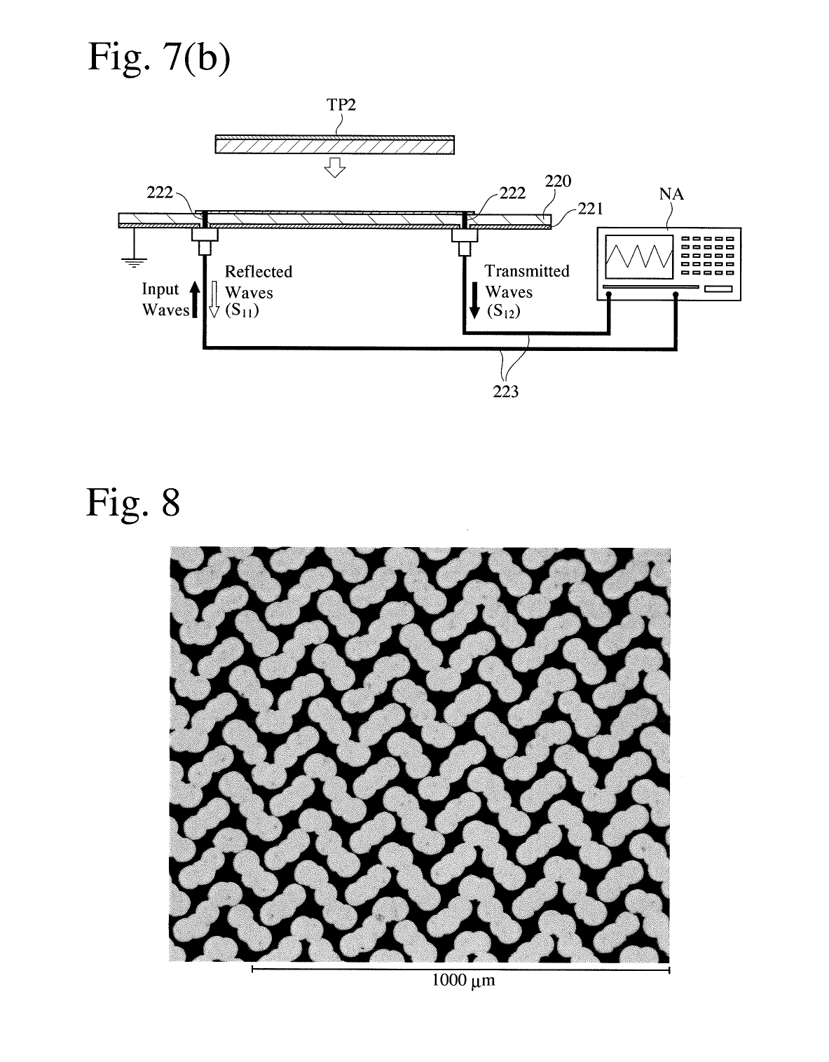

Using a system comprising a 50-Ω microstripline MSL (64.4 mm×4.4 mm), an insulating substrate 220 supporting the microstripline MSL, a grounded electrode 221 attached to a lower surface of the insulating substrate 220, conductive pins 222, 222 connected to both ends of the microstripline MSL, a network analyzer NA, and coaxial cables 223, 223 connecting the network analyzer NA to the conductive pins 222, 222 as shown in FIGS. 7(a) and 7(b), a test piece TP2 of each near-field electromagnetic wave absorbing film 1 is adhered to the microstripline MSL to measure its reflected wave power S₁₁ and transmitted wave power S₂₁ to an input electromagnetic wave of 0.1-6 GHz, thereby determining its transmission attenuation power ratio Rtp by the following formula (1):

Rtp=−10×log [10^{S21/10}/(1−10^{S11/10})] (1).

(2) Noise Absorption Ratio

In the system shown in FIGS. 7(a) and 7(b), input power Pᵢₙ=reflected wave power S₁₁+transmitted wave power S₂₁+absorbed power (power loss) Pₗₒₛₛ. Accordingly, the noise absorption ratio Pₗₒₛₛ/Pᵢₙ is determined by subtracting the reflected wave power S₁₁ and the transmitted wave power S₂₁ from the input power Pᵢₙ, and dividing the resultant power loss Pₗₒₛₛ by the input power Pᵢₙ.

The present invention will be explained in more detail referring to Examples below without intention of restriction.

### Example 1, and Comparative Examples 1 and 2

Each thin Al film 11 as thick as 80 nm was formed on a PET film 10 as thick as 16 μm by a vacuum vapor deposition method, and provided with plural lines of laser-etched openings 12 of 60 μm in diameter extending and crossing in two directions by a 3-Axis hybrid laser marker (MD-X1000 available from Keyence Corporation), to produce a near-field electromagnetic wave absorbing film 1 shown in FIGS. 8-10.

The electric resistance of a square test piece TP1 (10 cm×10 cm) cut out of each near-field electromagnetic wave absorbing film 1 was measured by the method described in Section [1] (4). The light transmittance of each near-field electromagnetic wave absorbing film 1 was measured with laser rays having a wavelength of 660 nm. The results are shown in Table 1.

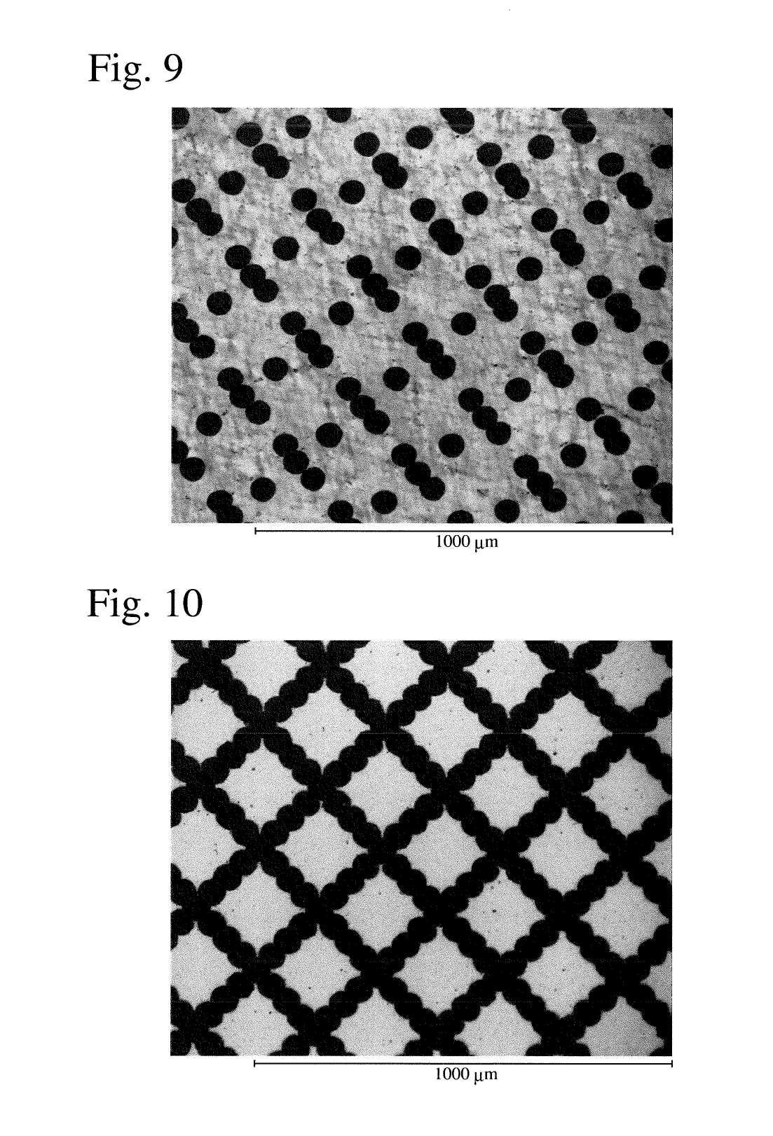

TABLE 1

| No. | Example 1 | Com. Ex. 1 | Com. Ex. 2 |
|---|---|---|---|
| Corresponding Figure | FIG. 8 | FIG. 9 | FIG. 10 |
| Crossing Angle θ ⁽¹⁾ (°) | 90 | 90 | 90 |
| Maximum Width Wmax⁽²⁾ (μm) | 15 | 60 | 0 |
| Average Width Wav⁽²⁾ (μm) | 8 | 50 | 0 |
| Electric Resistance (Ω/100 cm²) | 100 | 2 | ∞ |
| Light Transmittance (%) | 70 | 25 | 50 |

Note:
⁽¹⁾ The crossing angle θ of laser-etched opening lines.
⁽²⁾Measured in bridge-like remaining portions of the thin metal film.

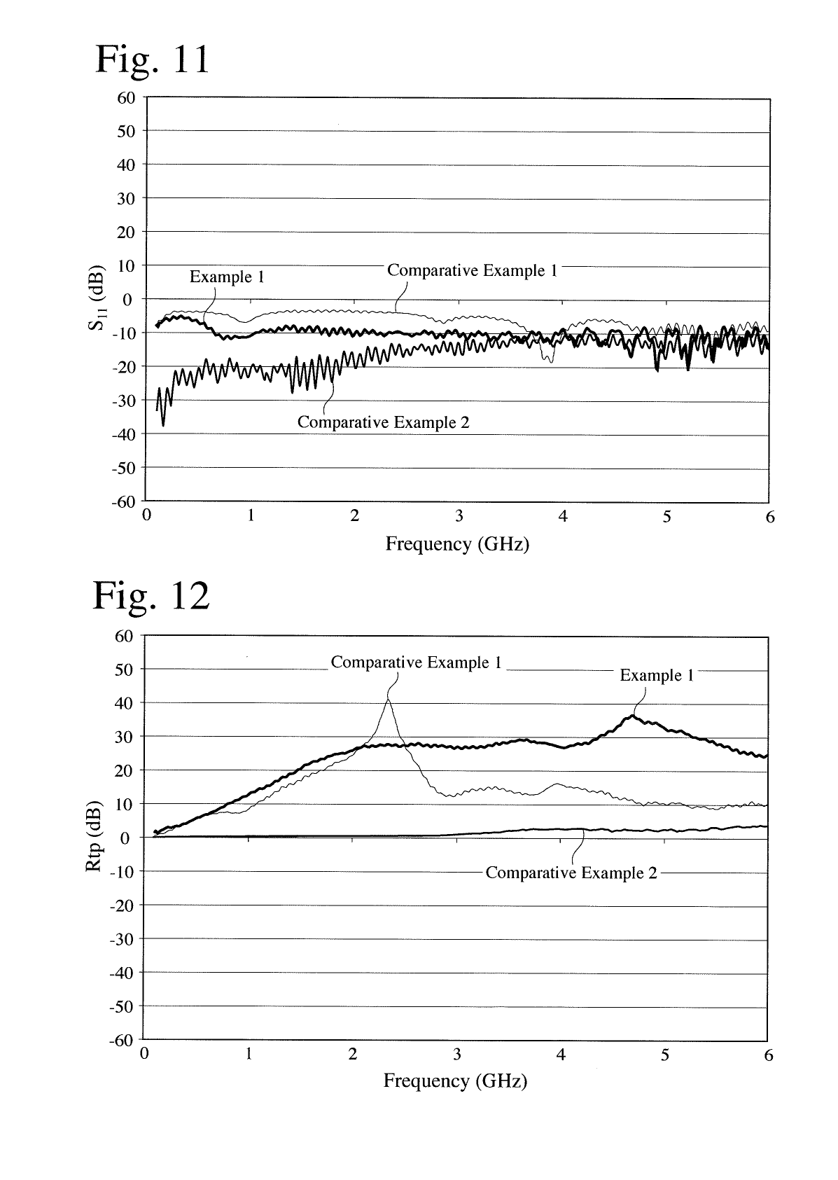

A test piece TP2 (55.2 mm×4.7 mm) cut out of each near-field electromagnetic wave absorbing film 1 was adhered to a microstripline MSL in the system shown in FIGS. 7(a) and 7(b), to measure reflected wave power S₁₁ and transmitted wave power S₂₁ relative to input power Pᵢₙ in a frequency range of 0.1-6 GHz. The reflected wave power S₁₁ and the transmitted wave power S₂₁ were measured by the method described in Section [2] (1) and (2), to determine S₁, and a transmission attenuation power ratio Rtp in a frequency range of 0.1-6 GHz. The S₁, and the transmission attenuation power ratio Rtp in a frequency range of 0.1-6 GHz are shown in FIGS. 11 and 12, respectively. As is clear from FIG. 11, too much wave power was reflected in Comparative Example 1 having too few laser-etched openings 12 (too low electric resistance and light transmittance). As is clear from FIG. 12, the transmission attenuation power ratio Rtp was low in Comparative Example 2 having excessive laser-etched openings 12 (too high electric resistance).

### Example 2, and Comparative Examples 3 and 4

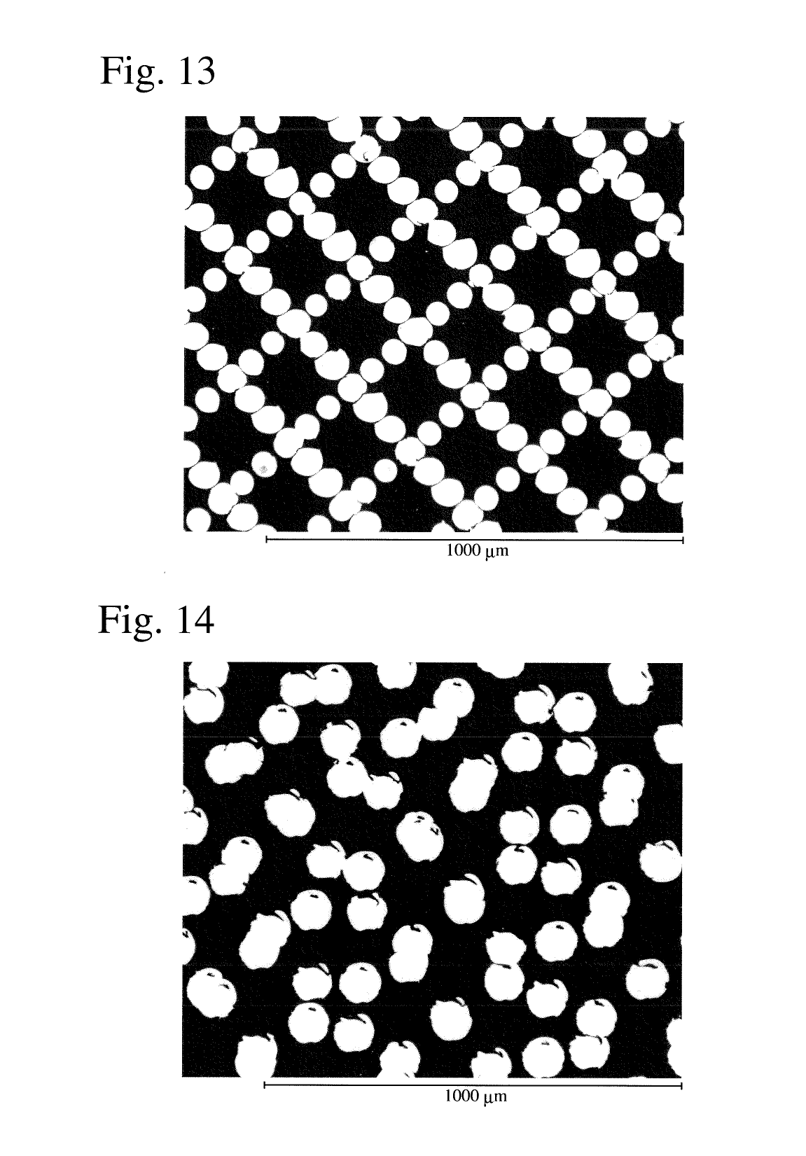

Each thin Ni film 11 as thick as 50 nm was formed on a PET film 10 as thick as 16 μm by a vacuum vapor deposition method, and provided with plural lines of laser-etched openings 12 of 60 μm in diameter extending and crossing in two directions by a 3-Axis hybrid laser marker (MD-X1000 available from Keyence Corporation), to produce a near-field electromagnetic wave absorbing film 1 shown in FIGS. 13-15. The electric resistance and light transmittance of each near-field electromagnetic wave absorbing film 1 were measured by the same methods as in Example 1. The results are shown in Table 2.

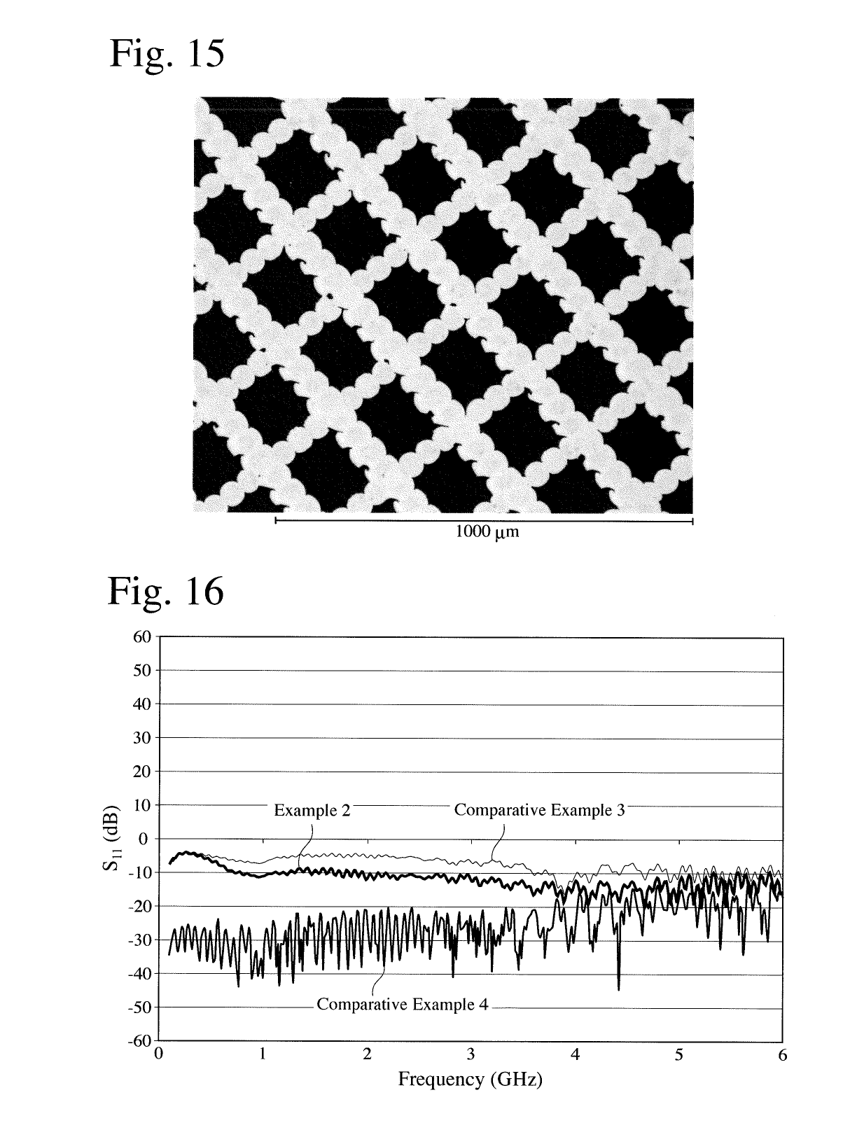

TABLE 2

| No. | Example 2 | Com. Ex. 3 | Com. Ex. 4 |
|---|---|---|---|
| Corresponding Figure | FIG. 13 | FIG. 14 | FIG. 15 |
| Crossing Angle θ ⁽¹⁾ (°) | 90 | 90 | 90 |
| Maximum Width Wmax⁽²⁾ (μm) | 15 | 60 | 0 |
| Average Width Wav⁽²⁾ (μm) | 7 | 50 | 0 |
| Electric Resistance (Ω/100 cm²) | 60 | 6 | ∞ |
| Light Transmittance (%) | 40 | 30 | 50 |

Note:
⁽¹⁾ The crossing angle θ of laser-etched opening lines.
⁽²⁾Measured in bridge-like remaining portions of the thin metal film.

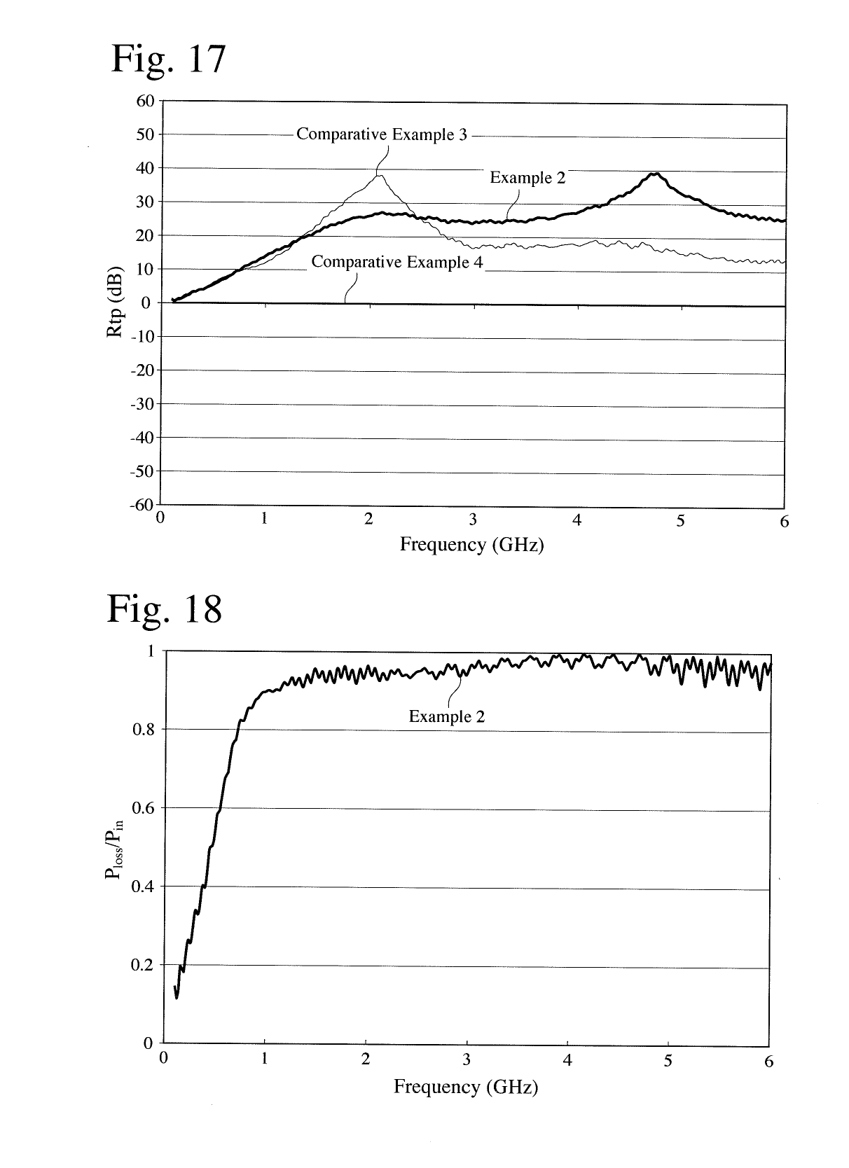

The S₁₁, transmission attenuation power ratio Rtp and noise absorption ratio Pₗₒₛₛ/Pᵢₙ of each near-field electromagnetic wave absorbing film 1 in a frequency range of 0.1-6 GHz were measured by the same methods as in Example 1. The S₁₁ and the transmission attenuation power ratio Rtp in a frequency range of 0.1-6 GHz are shown in FIGS. 16 and 17, respectively. The noise absorption ratio Pₗₒₛₛ/Pᵢₙ of Example 2 is shown in FIG. 18. As is clear from FIG. 16, too much wave power was reflected in Comparative Example 3 having too few laser-etched openings 12 (too low electric resistance and light transmittance). As is clear from FIG. 17, the transmission attenuation power ratio Rtp was low in Comparative Example 4 having excessive laser-etched openings 12 (too high electric resistance). Further, as is clear from FIG. 18, Example 2 meeting the requirements of the present invention with respect to laser-etched openings 12, electric resistance and light transmittance exhibited a high noise absorption ratio Pₗₒₛₛ/Pᵢₙ.

### Effects of the Invention

The near-field electromagnetic wave absorbing film of the present invention has excellent electromagnetic wave absorbability with small anisotropy, because laser-etched opening lines are formed in two directions in a thin metal film; pluralities of laser-etched openings being arranged in each line such that at least part of adjacent laser-etched openings are separated; thin metal film portions remaining after forming the laser-etched openings being composed of wide remaining portions partitioned by the laser-etched opening lines, and narrow bridge-like remaining portions connecting the wide remaining portions, so that it has electric resistance of 50-300 Ω/100 cm² and light transmittance (measured with laser rays having a wavelength of 660 nm) of 30-80%. The near-field electromagnetic wave absorbing film of the present invention having such features is suitably usable as a noise suppression sheet for communications apparatuses such as cell phones, smartphones, wireless LAN, etc., and electronic appliances such as computers, etc.

### DESCRIPTION OF REFERENCE NUMERALS

1: Near-field electromagnetic wave absorbing film
10: Plastic film
11: Thin metal film
11a: Remaining thin metal film portion
12: Laser-etched opening
12a, 12b: Laser-etched opening line
13: Wide remaining portion
14: Bridge-like remaining portion
112: Integral opening
120: Electrode
121: Electrode body portion
122: Electrode extension
130: Transparent acrylic plate
140: Cylindrical weight
220: Insulating substrate
221: Grounded electrode
222: Conductive pin
223: Coaxial cable
D: Diameter of laser-etched opening
W: Width of bridge-like remaining portion
T: Centerline distance between adjacent laser-etched opening lines
TP1, TP2: Test piece of near-field electromagnetic wave absorbing film
MSL: Microstripline
NA: Network analyzer

1. A near-field electromagnetic wave absorbing film comprising a plastic film, and a single- or multi-layered thin metal film formed on a surface of the plastic film;
said thin metal film being provided with plural lines of laser-etched openings extending and crossing in two directions;
pluralities of said laser-etched openings being arranged in each line such that at least part of adjacent laser-etched openings are separated;
said laser-etched opening lines extending in two directions crossing at an angle of 45-90°;
each of said laser-etched opening lines being provided with pluralities of laser-etched openings merged into integral openings;
thin metal film portions remaining after forming said laser-etched openings being composed of wide remaining portions partitioned by said integral openings, and bridge-like remaining portions connecting adjacent wide remaining portions; and
said bridge-like remaining portions having widths of 20 μm or less;
whereby said near-field electromagnetic wave absorbing film has electric resistance of 50-300 Ω/100 cm² and light transmittance (measured with laser rays having a wavelength of 660 nm) of 30-80%.

2. The near-field electromagnetic wave absorbing film according to claim 1, wherein said bridge-like remaining portions have an average width of 2-15 μm.

3. (canceled)

4. The near-field electromagnetic wave absorbing film according to claim 1, wherein said laser-etched openings have diameters of 100 μm or less.

5. The near-field electromagnetic wave absorbing film according to claim 1, wherein the centerline distance between adjacent laser-etched opening lines is 1.5-5 times the diameters of said laser-etched openings.

6. The near-field electromagnetic wave absorbing film according to claim 1, wherein the thickness of said thin metal film is 10-300 nm.

7. The near-field electromagnetic wave absorbing film according to claim 1, wherein said thin metal film is made of at least one metal selected from the group consisting of aluminum, copper, silver, tin, nickel, cobalt, chromium, and alloys thereof.
